(19) United States
(12) Patent Application Publication
(10) Pub. No.: US 2006/0090853 A1
(43) Pub. Date: May 4, 2006

(54) Substrate processing system for performing exposure process in gas atmosphere

(76) Inventors: Shusaku Kido, Kagoshima (JP); Yoshihide Iio, Kagoshima (JP); Masaki Ikeda, Kagoshima (JP)

Correspondence Address: Muirhead and Saturnelli, LLC, Suite 1001, 200 Friberg Parkway, Westborough, MA, 01581, US

(21) Appl. No.: 11/293,987

(22) Filed: Dec. 5, 2005

Related U.S. Application Data
(63) Continuation of application No. 10/226,961, filed on Aug. 23, 2002.

(30) Foreign Application Priority Data
Aug. 28, 2001 (JP) 2001-258187
Jul. 25, 2002 (JP) 2002-216877

(51) Int. Cl. H01L 21/306

(52) U.S. Cl. 156/345.33

(57) ABSTRACT

A substrate processing system which sprays exposure process gas onto a substrate disposed within a chamber. The substrate processing system is used, for example, for performing an exposure process of an organic film formed on a substrate in a gas atmosphere obtained by vaporizing an organic solvent solution for dissolving and reflowing an organic film. The substrate processing system comprises: the chamber having at least one gas inlet and at least one gas outlets; a gas introducing means which introduces the exposure process gas into the chamber via the gas inlet; and a gas distributing means. The gas distributing means separates an inner space of the chamber into a first space into which the exposure process gas is introduced via the gas inlet and a second space in which the substrate is disposed. The gas distributing means has a plurality of openings via which the first space and the second space communicate with each other and introduces the exposure process gas introduced into the first space into the second space via the openings.

### FIELD OF THE INVENTION

The present invention relates generally to a substrate processing system which performs a gas exposure process or treatment onto a substrate used for forming a semiconductor element by using various gas atmosphere. More particularly, the present invention relates to a substrate processing system in which an exposure process of an organic film formed on a substrate surface is performed in a gas atmosphere obtained by vaporizing an organic solvent solution for dissolving and reflowing an organic film.

### BACKGROUND OF THE INVENTION

An example of a conventional semiconductor processing system which performs various processing onto a substrate used for forming a semiconductor element is disclosed in Japanese patent laid-open publication No. 11-74261. The system disclosed in this publication is a device for flattening unevenness of the surface of the substrate on which semiconductor elements are formed, by using a coating film made of organic material. By using this system, it is possible to form a flat film having good flatness and having good resistance to crack caused by heat treatment.

With reference to FIG. 15, an explanation will now be made on the processing system disclosed in this publication.

As shown in FIG. 15, this processing system comprises a sealed chamber 501, and a hot plate 502 disposed on the bottom surface of the sealed chamber 501. The processing system also comprises a lid 503 which covers the top portion of the sealed chamber 501, and a heater 504 which surrounds the sealed chamber 501 in order to keep the temperature within the sealed chamber 501 at the same temperature as that of the hot plate 502.

At upper portions of the sealed chamber 501, there are provided a gas inlet 505 and a gas outlet 506 at portions between the sealed chamber 501 and the lid 503.

In the method described in the Japanese patent laid-open publication No. 11-74261, a wafer on which polysiloxane coating liquid is coated is transported onto the hot plate 502 within the sealed chamber 501. In this case, the temperature of the hot plate 502 is set at 150° C. Also, from the gas inlet 505, dipropylene-glycol-monoethyl-ether which is heated to 150° C is introduced into the sealed chamber 501 as a solvent gas. In this condition, the wafer is exposed to the solvent gas for 60 seconds. Thereafter, introduction of the solvent gas is stopped. Then, nitrogen is introduced into the chamber 501 and this condition is kept for 120 seconds. The wafer is then carried out from the chamber 501.

In this processing system, in place of using a conventional simple heating process which uses a hot plate and in which solvent contained in a coating film of polysiloxane coating liquid is rapidly evaporated, the solvent is gradually evaporated. This is done by retarding evaporation of the solvent in the coating film by introducing the solvent which is the same as that of the polysiloxane coating liquid into the chamber 501, and by planarizing the coating film while keeping the coating film in a fluid condition. Therefore, in this method, the evaporation of the solvent in the coating film is retarded and, therefore, cracks are not produced by the rapid contraction of the coating film, like the conventional simple heating process, and it is possible to obtain a planarized film having good flatness.

In the system mentioned above with reference to FIG. 15, it is possible to form a simply flat film on a substrate.

However, it is impossible to use the above-mentioned system for performing a reflow process of photo resist patterns described in Japanese patent application No. 2000-175138 which was previously filed by the inventors of this application.

Here, with reference to FIGS. 16A-16C and FIGS. 17A-17B, a schematic explanation will now be made on the above-mentioned reflow process of the photo resist patterns.

FIGS. 16A-16C are cross sectional views schematically illustrating a part of process steps for manufacturing a semiconductor element, i.e., a thin film transistor, by using a reflow process of photo resist patterns.

First, as shown in FIG. 16A, on a transparent insulating substrate 511, a gate electrode 512 is formed, and the transparent insulating substrate 511 and the gate electrode 512 are covered by a gate insulating film 513.

Also, on the gate insulating film 513, a semiconductor film 514 and a chromium layer 515 are deposited. Thereafter, a coating film is applied by spin coating, and exposure and development processes are performed. Thereby, photo resist patterns 516 are formed as illustrated in FIG. 16A.

Next, by using the photo resist patterns 516 as a mask, only the chromium layer 515 is etched, and thereby source/drain electrodes 517 are formed as shown in FIG. 16B.

Then, a reflow of the photo resist patterns 516 is executed to form a photo resist pattern 536 as shown in FIG. 16C. The photo resist pattern 536 covers at least an area which should not be etched thereafter, in this case, an area corresponding to a back-channel region 518 of the TFT as shown in FIG. 17A which is formed later.

By using this photo resist pattern 536 as a mask, the semiconductor film 514 is etched, and a semiconductor film pattern 518, i.e., the back-channel region 518, is formed as shown in FIG. 17A.

In this way, when the reflow of the photo resist patterns 516 is performed as mentioned above, an area of the semiconductor film pattern 518 becomes wider than a portion of the semiconductor film pattern 518 just under the source/drain electrodes 517, by a distance L in lateral direction, as shown in the cross sectional view of FIG. 17A and in a plan view of FIG. 17B. Here, this distance L is called a reflow distance of the photo resist pattern 536.

The photo resist pattern 536 enlarged in this way determines the size and shape of the portion of the semiconductor film 514 which is under the photo resist pattern 536 and which is etched by using the photo resist pattern 536 as a mask. Therefore, it is important that the reflow distance L can be uniformly and precisely controlled throughout the whole area of the substrate.

However, in the above-mentioned method disclosed in Japanese patent laid-open publication No. 11-74261 which uses the structure of FIG. 15, the gas only flows through the surface of the wafer 502 and the gas does not uniformly flow throughout the whole area of the wafer 502. Therefore, it is impossible to precisely control the reflow distance L to a desired value.

### SUMMARY OF THE INVENTION

Therefore, it is an object of the present invention to provide a substrate processing system in which, when element patterns are formed by using a reflow process of photo resist patterns, a reflow distance L of the photo resist patterns can be precisely controlled.

It is another object of the present invention to provide a substrate processing system in which, when element patterns are formed by using a reflow process of photo resist patterns, a reflow distance L of the photo resist patterns can be precisely and reproducibly controlled.

It is still another object of the present invention to a substrate processing system in which, when element patterns are formed by using a reflow process of patterns of a coating film, a reflow process of the coating film patterns can be done with high precision and reproducibility while securing a desired film thickness of the coating film as a mask.

It is still another object of the present invention to obviate the disadvantages of a conventional substrate processing system.

According to a first aspect of the present invention, there is provided a substrate processing system which sprays exposure process gas onto a substrate disposed within a chamber, the substrate processing system comprising: the chamber having at least one gas inlet and at least one gas outlets; a gas introducing means which introduces the exposure process gas into the chamber via the gas inlet; and a gas distributing means; wherein the gas distributing means separates an inner space of the chamber into a first space into which the exposure process gas is introduced via the gas inlet and a second space in which the substrate is disposed; the gas distributing means has a plurality of openings via which the first space and the second space communicate with each other; and the gas distributing means introduces the exposure process gas introduced into the first space into the second space via the openings.

According to a second aspect of the present invention, there is provided a substrate processing system which sprays exposure process gas onto each of a plurality of substrates disposed parallel within a chamber in a vertical direction, the substrate processing system comprising: the chamber having at least one gas inlet and at least one gas outlets; a gas introducing means which introduces the exposure process gas into the chamber via the gas inlet; and a gas distributing means each of which is provided for corresponding one of the plurality of substrates; wherein the gas distributing means has a plurality of openings, and the exposure process gas introduced via the gas inlet into the chamber is sprayed onto the substrate via the openings.

It is preferable that the chamber has a plurality of gas inlets, and the first space is divided into a plurality of small spaces by surrounding a predetermined number of gas inlets with partitions.

It is also preferable that the substrate processing system further comprises a gas flow rate control mechanism for each of the gas inlets.

It is further preferable that substrate processing system further comprises one or more gas diffusing members which are disposed in the first space and which diffuse the exposure process gas introduced via the gas inlet to uniform a density of the exposure process gas within the chamber.

It is advantageous that the gas distributing means comprises a curved plate member which is convex or concave toward the substrate.

It is also advantageous that the substrate processing system further comprises a gas spouting range defining means which is disposed such that the gas spouting range defining means overlaps the gas distributing means and which closes a predetermined number of openings among the openings formed in the gas distributing means, thereby defining a gas spouting range of the exposure process gas.

It is further advantageous that the gas distributing means is rotatable around the center thereof.

According to a third aspect of the present invention, there is provided a substrate processing system which sprays exposure process gas onto a substrate disposed within a chamber, the substrate processing system comprising: the chamber having at least one gas inlet and at least one gas outlets; a gas introducing means which introduces the exposure process gas into the chamber via the gas inlet; and gas distributing means which sprays the exposure process gas introduced into the chamber onto the substrate; wherein the gas distributing means is movable within the chamber along an upper wall of the chamber.

It is preferable that the gas distributing means is rotatable around the center axis thereof.

It is also preferable that the substrate processing system further comprises a stage on which the substrate is placed, the stage being movable up and down.

It is further preferable that the substrate processing system further comprises a stage on which the substrate is placed, the stage being rotatable around the center axis thereof.

It is advantageous that the substrate processing system further comprises a substrate temperature control means which controls the temperature of the substrate.

It is also advantageous that the substrate processing further comprises a gas temperature control means which controls the temperature of the exposure process gas.

It is further advantageous that the substrate processing further comprises a stage on which the substrate is placed, and the substrate temperature control means controls the temperature of the substrate by controlling the temperature of the stage.

It is preferable that the pressure within the chamber is in a range from −20 KPa to +20 KPa.

It is also preferable that the substrate processing system further comprises a plasma generating means which generates plasma within the chamber.

It is further preferable that the plasma generating means comprises an upper electrode disposed above the substrate and a lower electrode disposed below the substrate, wherein one of the upper electrode and the lower electrode is grounded, and the other one of the upper electrode and the lower electrode is coupled with the ground via a high frequency power source.

It is advantageous that the substrate processing system further comprises: a reduced pressure transport chamber which is communicated with the chamber and which is used for transporting the substrate into the chamber under a reduced pressure condition and for transporting the substrate out from the chamber under a reduced pressure condition; and a pressure controlled transport chamber which is communicated with the reduced pressure transport chamber, which is used for introducing the substrate from outside under the atmospheric pressure condition and for transporting the substrate into the reduced pressure transport chamber under a reduced pressure condition and which is used for transporting the substrate out from the reduced pressure transport chamber under a reduced pressure condition and for transporting the substrate outside under the atmospheric pressure condition.

By using the substrate processing system according to a first aspect of the present invention, exposure process gas is sprayed approximately uniformly onto the whole surface of a substrate by a gas distributing means. Therefore, it becomes possible to control a reflow distance L throughout the whole surface of the substrate with high precision.

By using the substrate processing system according to a second aspect of the present invention, it is possible to process a plurality of substrates simultaneously and thereby to greatly improve a processing efficiency of the substrates.

In the substrate processing system according to the third aspect of the present invention, the gas distributing means moves along the upper wall portion of the chamber in the longitudinal direction of the substrate. While the gas distributing means is moving in the longitudinal direction, the gas distributing means sprays the exposure process gas onto the substrate. In this way, the gas distributing means sprays the exposure process gas onto the substrate while the gas distributing means scans along the substrate. Therefore, it is possible to spray the exposure process gas uniformly onto the substrate.

As an example, a flow rate of the exposure process gas is preferably 2-10 liter/minute. However, the flow rate of the exposure process gas can be 1-100 liter/minute.

A temperature of the exposure process gas is preferably 20-25 degrees Centigrade. However, the temperature of the exposure process gas can be 18-40 degrees Centigrade.

A distance between the substrate and the gas distributing means is preferably 5-15 mm. However, the distance between the substrate and the gas distributing means can be 2-100 mm.

A temperature of the stage is preferably 24-26 degrees Centigrade. However, the temperature of the stage can be 18-40 degrees Centigrade.

A pressure within the chamber is preferably from −20 to +2 KPa. However, the pressure within the chamber can be a value from −50 to +50 KPa.

### BRIEF DESCRIPTION OF THE DRAWINGS

These and other features, and advantages, of the present invention will be more clearly understood from the following detailed description taken in conjunction with the accompanying drawings, in which like reference numerals designate identical or corresponding parts throughout the figures, and in which:

FIG. 1 is a schematic cross sectional view illustrating a structure of a substrate processing system according to a first embodiment of the present invention;

FIG. 2 is a perspective view illustrating a gas spouting plate and a frame for the gas spouting plate used in the substrate processing system shown in FIG. 1;

FIG. 3 is a perspective view illustrating an example of a gas diffusing member used in the substrate processing system shown in FIG. 1;

FIG. 4 is a graph showing a relationship between a reflow distance in lateral direction of a coating film pattern and a reflow time;

FIG. 5 is a graph showing a relationship between uniformity of reflow distances within a substrate and a vapor flow rate, after performing a reflow process of coating film patterns;

FIG. 6 is a graph showing a relationship between a uniformity of reflow distances within a substrate and a distance between a lifting stage and a gas spouting plate, after reflowing coating film patterns;

FIG. 7 is a graph showing a relationship between a reflow rate of a coating film pattern and a temperature of a lifting stage;

FIG. 8 is a cross sectional view illustrating a schematic structure of a substrate processing system according to a second embodiment of the present invention;

FIG. 9 is a cross sectional view illustrating an example of a substrate processing system in which partitions are provided such that each one of gas introducing pipes is surrounded with the partitions;

FIG. 10 is a cross sectional view illustrating an example of a substrate processing system in which only one gas introducing pipe is disposed in one of a plurality of small spaces;

FIG. 11 is a cross sectional view illustrating a schematic structure of a substrate processing system according to a third embodiment of the present invention;

FIG. 12 is a cross sectional view illustrating a schematic structure of a substrate processing system according to a fourth embodiment of the present invention;

FIG. 13 is a cross sectional view illustrating a schematic structure of a substrate processing system according to a fifth embodiment of the present invention;

FIG. 14 is a plan view illustrating a schematic structure of a substrate processing system according to a sixth embodiment of the present invention;

FIG. 15 is a cross sectional view illustrating a conventional processing system for planarizing a coating film;

FIGS. 16A-16C are cross sectional views schematically illustrating a part of process steps for manufacturing a thin film transistor by using a conventional processing system for planarizing a coating film;

FIG. 17A is a cross sectional view schematically illustrating a part of process steps for manufacturing a thin film transistor performed after the process steps illustrated in FIGS. 16A-16C; and

FIG. 17B is a partial plan view of a workpiece illustrated in the cross sectional view of FIG. 17A.

### DESCRIPTION OF A PREFERRED EMBODIMENT

With reference to the drawings, embodiments of the present invention will now be described.

### First Embodiment

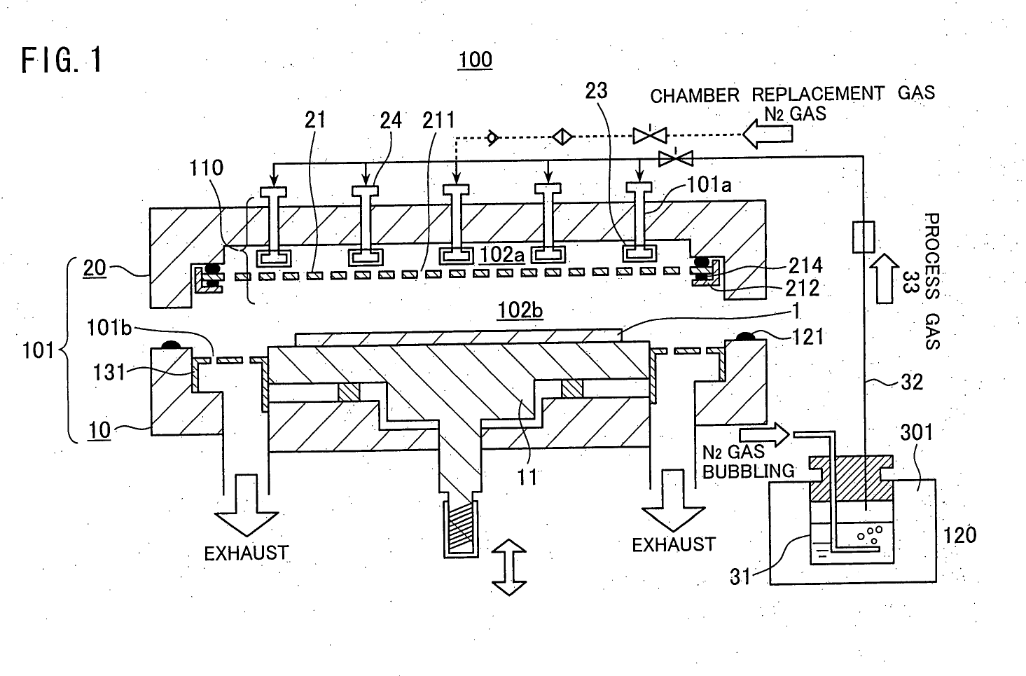

FIG. 1 is a schematic cross sectional view illustrating a structure of a substrate processing system according to a first embodiment of the present invention. The substrate processing system according to the first embodiment of the present invention is a device which uniformly sprays an exposure process gas onto a substrate disposed,within a chamber.

As shown in FIG. 1, the substrate processing system 100 generally comprises a exposure process chamber 101, a gas introducing mechanism 120 which introduces an exposure process gas into the exposure process chamber 101, and a gas spray mechanism 110 which sprays the exposure process gas onto a substrate.

The exposure process chamber 101 has a lower chamber 10 and an upper chamber 20. The lower chamber 10 and the upper chamber 20 are joined together via an O-ring 121 attached to the lower chamber 10, and thereby an airtight space is formed within the chamber 101.

The exposure process chamber 101 has a plurality of gas inlets 101a and two gas outlets 101b. Although not shown in the drawing, each of the gas outlets 101b has an opening degree control mechanism, and an opening ratio of each of the gas outlets 101b can be freely controlled.

Within the exposure process chamber 101, there is disposed a lifting stage 11 which is movable up and down in a vertical direction. A substrate 1 is placed on the upper surface of the lifting stage 11 in a horizontal attitude. The lifting stage 11 is movable up and down within a range of 1-50 mm.

The gas spray mechanism 110 comprises a plurality of gas introducing pipes 24 each of which is inserted into a corrseponding one of a plurality of gas inlets 101a formed in the upper chamber 20, gas diffusing members 23 each of which is attached to an end portion of the gas introducing pipe 24, a gas spouting plate 21, and a frame 212 for the gas spouting plate 21 which fixes the gas spouting plate 21 and which defines an area of gas spouting.

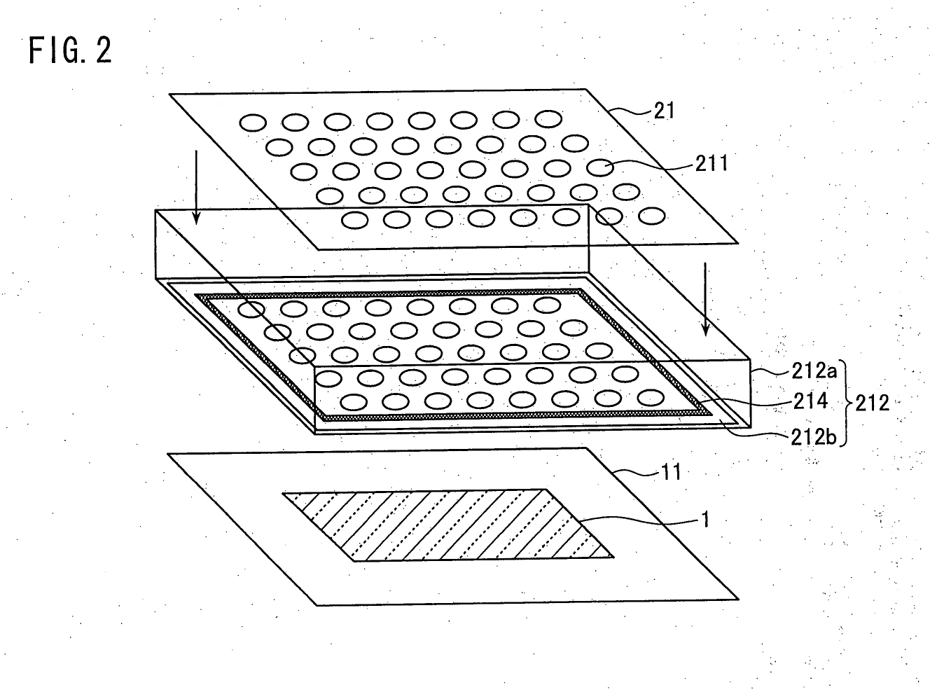

FIG. 2 is a perspective view illustrating the gas spouting plate 21 and the frame 212 for the gas spouting plate 21.

As shown in FIG. 2, the gas spouting plate 21 is formed of a flat board shaped member, and has a plurality of apertures 211 formed in a matrix. The apertures 211 are disposed such that the apertures 211 are formed in an area covering whole area of the substrate 1 which is disposed at a location under the gas spouting plate 21.

In this embodiment, each of the apertures 211 has a diameter of 0.5-3 mm, and a space between adjacent apertures 211 is preferably 1-5 mm.

As shown in FIG. 1, the gas spouting plate 21 is disposed horizontally between the gas diffusing members 23 and the substrate 1. The gas spouting plate 21 divides the inner space of the exposure process chamber 101 into a first space 102a into which the exposure process gas is introduced via the gas introducing pipes 24, and a second space 102b in which the substrate 1 is disposed. The first space 102a and the second space 102b communicate with each other via the apertures 211, and the exposure process gas introduced into the first space 102a is introduced into the second space 102b via the apertures 211.

As shown in FIG. 2, the frame 212 for the gas spouting plate 21 comprises a frame-like sidewall portion 212a, and a frame-like extended portion 212b which extends from the lower end of the sidewall portion 212a toward inside.

The gas spouting plate 21 is adhered to the extended portion 212b via a sealing material 214. Thereby, the gas spouting plate 21 and the frame 212 for the gas spouting plate 21 are tightly coupled without a gap therebetween, and the exposure process gas does not leak out from the periphery of the gas spouting plate 21.

The length of extension of the extended portion 212b is appropriately set so that some of the apertures 211 formed in the gas spouting plate 21 are closed, and thereby an area of the gas spouting plate 21 from which the exposure process gas is blown is defined.

In this embodiment, the height of the sidewall portion 212a is 5 mm, and the length, i.e., the lateral width, of the extended portion 212b is 10 mm. The frame 212 for the gas spouting plate 21 is disposed at a height of 10 mm above the substrate 1.

Each of the gas diffusing members 23 disposed in the first space 102a is made, for example, of a box-shaped member, and the box-shaped member has a plurality of holes at the outer wall thereof.

The exposure process gas spouted via the gas introducing pipes 24 hits the inner wall of each of the gas diffusing members 23 and is temporarily stored within the gas diffusing members 23, so that the exposure process gas is uniformly diffused within the gas diffusing members 23. Therefore, the density of the exposure process gas becomes uniform within the gas diffusing members 23, and thereafter the exposure process gas is spouted out of the gas diffusing members 23.

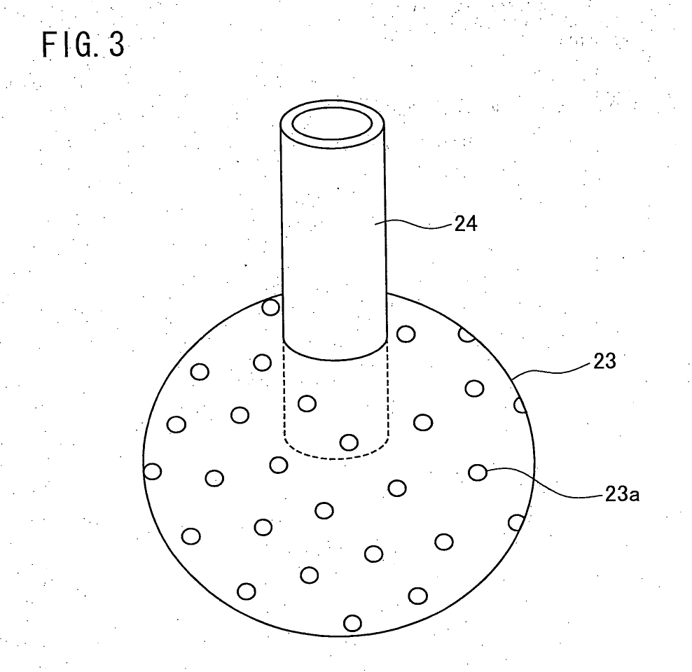

It should be noted that the shape and the like of the gas diffusing members 23 is not limited to that mentioned above but can be any other shape and the like. FIG. 3 illustrates an example of another gas diffusing member 23.

The gas diffusing member 23 shown in FIG. 3 has a hollow spherical shape, and has a plurality of holes 23a are formed on the outer surface of the gas diffusing member 23. The inside space of the gas diffusing member 23 communicates with the outside space thereof via the plurality of holes 23a.

The gas introducing pipe 24 extends to the center of the spherical shaped gas diffusing member 23, and thereby the exposure process gas is spouted inside the gas diffusing member 23 from the center of the gas diffusing member 23. Therefore, the exposure process gas reaches from the center of the gas diffusing member 23 to any hole 23a via an equal distance. In this way, the exposure process gas is diffused when it reaches the holes 23a, and the density distribution thereof is uniformed.

As shown in FIG. 1, the gas introducing mechanism 120 comprises a vapor producing device 31, and a gas pipe 32 which supplies exposure process gas produced in the vapor producing device 31 to each of the gas introducing pipes 24.

The vapor producing device 31 has a liquid stored therein for producing the exposure process gas. The vapor producing device 31 injects nitrogen (N₂) gas into the liquid as a material of the vapor such that bubbles are produced within the liquid. Thereby, the vapor is produced from the liquid, and a gas including the vapor and the N₂ gas is produced and supplied to the exposure process chamber 101 as the exposure process gas 33.

Also, the gas introducing mechanism 120 has a container or reservoir 301 which surrounds the vapor producing device 31. In the reservoir 301, temperature control liquid is stored. By the heat transfer from the temperature control liquid, the temperature of the liquid for producing the exposure process gas within the vapor producing device 31 is controlled. Thereby, the temperature of the exposure process gas 33 is controlled.

As the temperature control liquid, a liquid obtained by mixing ethylene-glycol and pure water. The temperature control liquid may by any liquid which has a high heat conductivity and which has a freezing point lower than 0 (zero) ° C. Temperature control of the temperature control liquid can be done, for example, by heating the liquid by using a heater, by electronically cooling the liquid by using refrigerant, by using factory cooling water which is used for cooling various manufacturing system in a factory, and the like.

The flow rate of the exposure process gas 33 supplied into the exposure process chamber 101 is controlled to be a value within a range of 1-50 L/min.

The exposure process gas blown onto the substrate 1 within the exposure process chamber 101 is exhausted via the gas outlets 101b formed in the periphery of the lower chamber 10, by using a vacuum pump not shown in the drawing. Each of the gas outlets 101b is covered by an exhaust hole plate 131 which has a plurality of holes. By such exhaust hole plates 131, the exposure process gas is uniformly exhausted after the treatment or process.

In this embodiment, each of the holes provided in the exhaust hole plate 131 has a diameter of 2-10 mm, and the space between adjacent holes is 2-50 mm.

Also, in order to obtain pure gas atmosphere within the exposure process chamber 101 and to control the processing or treatment time precisely by the second, it is necessary that replacement of gas within the exposure process chamber 101 can be performed in a short time.

From the result of experiments by the inventors, it was found that the vacuum pump used for exhausting the exposure process chamber 101 should have an exhaust ability which realizes an exhaust velocity or exhaust rate of at least 50 L/min or higher and which realizes a pressure within the exposure process chamber 101 of −100 KPa or lower after elapsing 1 (one) minute from the start of exhaust.

Next, an explanation will be made on an operation of the substrate processing system 100 according to an embodiment of the present invention and a processing method of a substrate 1 which uses the substrate processing system 100.

First, the substrate 1 to be processed is placed on the lifting stage 11, and the lower chamber 10 and the upper chamber 20 are tightly closed. The lifting stage 11 is raised or lowered, and the distance between the gas spouting plate 21 and the substrate 1 is adjusted to become 10 mm.

In order to realize pure gas atmosphere within the exposure process chamber 101, the exposure process chamber 101 is forcibly evacuated before introducing the exposure process gas into the chamber such that the pressure within the exposure process chamber 101 becomes approximately −70 KPa or lower, where the atmospheric pressure is assumed to be 0 KPa.

Then, a gas pressure of nitrogen gas to be injected into the vapor producing device 31 is adjusted to become 0.5 Kg/cm, and the flow rate of the nitrogen gas is adjusted to be 5.0 L/min. In these conditions, the nitrogen gas is injected into the processing liquid stored in the vapor producing device 31 such that the vaporized gas from the processing liquid is produced like bubbles.

In this way, the exposure process gas 33 which includes the gas vaporized from the processing liquid and nitrogen gas is produced and supplied to the gas pipe 32 at a gas flow rate of 5.0 L/min.

The exposure process gas 33 is transported and stored into the gas diffusing members 23 via the gas pipe 32 and the gas introducing pipes 24, and, in the gas diffusing members 23, the exposure process gas 33 is diffused such that the density of the exposure process gas 33 becomes approximately uniform. Thereafter, the exposure process gas 33 is spouted from the gas diffusing members 23 to the first space 102a.

The exposure process gas 33 spouted from each gas diffusing member 23 to the first space 102a has approximately uniform density and approximately uniform velocity. Also, the exposure process gas 33 is temporarily stored in the first space 102a and thereby the gas density is further uniformed. Therefore, the exposure process gas 33 is uniformly spouted into the second space 102b via the apertures 211 of the gas spouting plate 21, and is uniformly blown or sprayed onto the substrate 1 placed on the lifting stage 11.

It is also possible to omit the gas diffusing members 23 and to uniform the gas density only by using the gas spouting plate 21.

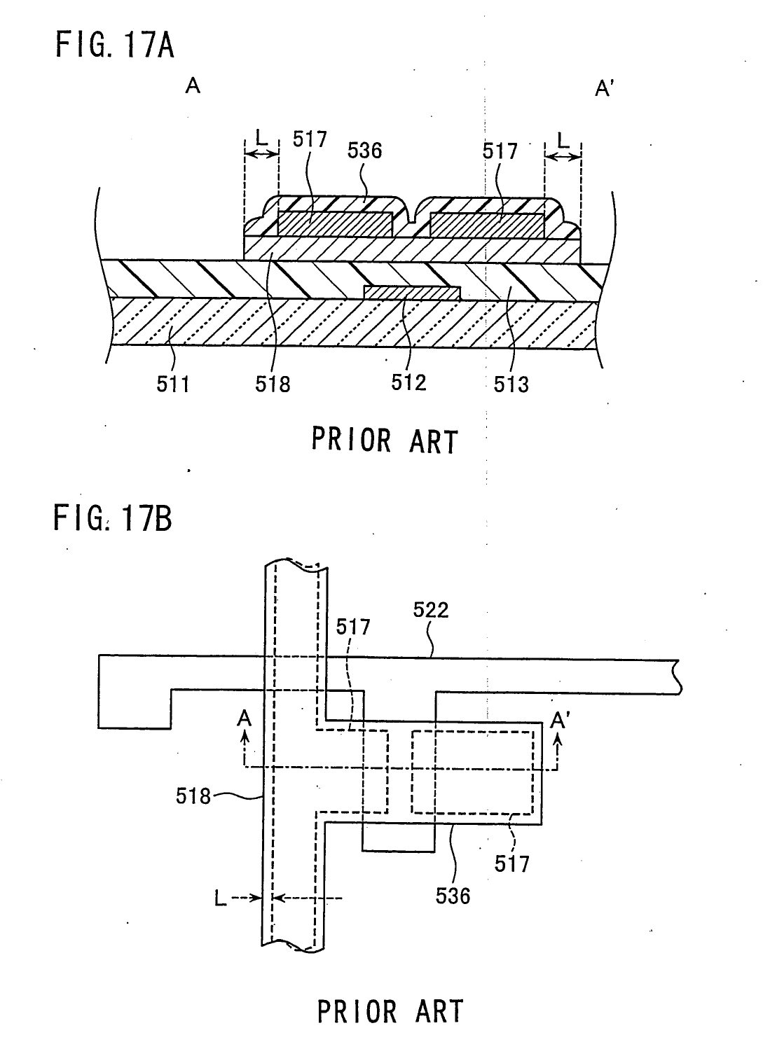

As a result of this process, reflow of photo resist patterns 516 occurs (see FIG. 17A).

Supply of the exposure process gas 33 is continued, via the gas pipe 32, the gas introducing pipes 24 and gas diffusing members 23, into the exposure process chamber 101, and when the pressure within the exposure process chamber 101 becomes a positive pressure, i.e., a pressure value equal to or larger than +0 KPa, the gas outlets 101b are opened.

As a treatment process condition, the pressure within the exposure process chamber 101 is controlled to become, for example, +0.2 KPa. In such case, degree of opening of the gas outlets 101b is controlled such that the pressure within the exposure process chamber 101 is maintained at +0.2 KPa.

In this case, as the processing pressure or treatment pressure, it is possible to select a value in a range from −50 KPa to +50 KPa. Preferably, the processing pressure is a value selected from a range between −20 KPa and +20 KPa. More preferably, the processing pressure is a value selected from a range between −5 KPa and +5 KPa, and an error of the processing pressure value is controlled to be equal to or smaller than ±0.1 KPa.

After elapsing a predetermined processing time, in order to quickly perform gas replacement, a method is used in which the exposure process gas is evacuated and is replaced by N₂ gas.

In this method, first, introduction of the exposure process gas 33 is stopped and, thereafter, the exposure process chamber 101 is vacuum evacuated to make the pressure within the exposure process chamber 101 approximately −70 KPa or lower. Also, a valve in a path shown by a dotted line in FIG. 1 is opened, and, as chamber replacement gas, inert gas such as nitrogen gas and the like is introduced into the exposure process chamber 101 at a flow rate of 20 L/min or higher. While introducing the inert gas, the exposure process chamber 101 is also vacuum evacuated for at least 10 seconds or more. At this time, the pressure within the exposure process chamber 101 is maintained at least at −30 KPa.

The vacuum evacuation is then stopped, and nitrogen gas is introduced into the exposure process chamber 101 such that the pressure within the exposure process chamber 101 becomes a positive pressure. When the pressure within the exposure process chamber 101 becomes approximately +2 KPa, introduction of the nitrogen gas for replacement is stopped.

Then, the upper chamber 20 and the lower chamber 10 are opened, and the processed substrate 1 is taken out.

An explanation will be made below on examples of photo resist materials used as materials of organic film patterns for use in this embodiment. As the photo resist materials, there are photo resist which is soluble in organic solvent and photo resist which is soluble in water.

As an example of the photo resist which is soluble in organic solvent, there is a photo resist which is obtained by adding photosensitive emulsion and additive to high polymer.

There are various kinds of high polymers. As a high polymer of polyvinyl system, there is polyvinyl cinnamic acid ester. As a high polymer of rubber system, there is a high polymer obtained by mixing cyclized polyisoprene, cyclized polybutadiene or the like with bisazide compound. As a high polymer of novolac resin system, there is a high polymer obtained by mixing cresol novolac resin with naphthoquinone diazo-5-sulfonate ester. As a high polymer of copolymerized resin system of acrylic acid, there are polyacrylic amide, polyamide acid and the like.

As examples of photo resist which is soluble in water, there are photo resists each of which is obtained by adding photosensitive emulsion and additive to a high polymer. As the high polymer, there is a high polymer of any one of or any combination of two or more of: polyacrylic acid, polyvinyl acetal, polyvinyl pyrrolidone, polyvinyl alcohol, polyethylene imine, polyethylene oxido, styrene-maleic acid anhydride copolymer, polyvinyl amine, polyallyl amine, oxazoline group containing water soluble resin, water soluble melamine resin, water soluble urea resin, alkyd resin, and sulfonamide.

Next, examples of chemical solutions used as solvent for dissolving a photo resist film.

1. When the Photo Resist is Soluble in Organic Solvent:

(a) Organic Solvent

As practical examples, organic solvent is shown below by dividing the organic solvent into organic solvent as upper concept and organic solvent as lower concept. Here, a symbol “R” designates alkyl group or substituent alkyl group, a symbol “Ar” designates phenyl group or aromatic ring other than phenyl group.

alcohol and the like (R—OH)

alkoxy-alcohol and the like

ether and the like (R—O—R, Ar—O—R, Ar—O—Ar)

ester and the like

ketone and the like

glycol and the like

alkylene glycol and the like

glycol ether and the like

As practical examples of the above-mentioned organic solvent, there are followings:

CH₃OH, C₂H₅OH, CH₃(CH₂)XOH

isopropyl alcohol (IPA)

ethoxyethanol

methoxyalcohol

long-chain alkyl ester

mono ethanolamine (MEA)

acetone

acetyl acetone

dioxan

ethyl acetate

butyl acetate

toluene

methyl ethyl ketone (MEK)

diethyl ketone

dimethyl sulfoxide (DMSO)

methyl isobutyl ketone (MIBK)

butyl carbitol

n-butyl acetate (nBA)

gamma-butyrolactone

ethyl cellosolve acetate (ECA)

ethyl lactate

ethyl pyruvic acid

2-heptanone (MAK)

3-methoxy butyl acetate

ethylene glycol

propylene glycol

butylene glycol

ethylene glycol monoethyl ether

diethylene glycol monoethyl ether

ethylene glycol monoethyl ether acetate

ethylene glycol monomethyl ether

ethylene glycol monomethyl ether acetate

ethylene glycol mono-n-butyl ether

polyethylene glycol

polypropylene glycol

polybutylene glycol

polyethylene glycol monoethyl ether

polydiethylene glycol monoethyl ether

polyethylene glycol monoethyl ether acetate

polyethylene glycol monomethyl ether

polyethylene glycol monomethyl ether acetate

polyethylene glycol mono-n-butyl ether

methyl-3-methoxypropionate (MMP)

propylene glycol monomethyl ether (PGME)

propylene glycol monomethyl ether acetate (PGMEA)

propylene glycol monopropyl ether (PGP)

propylene glycol monoethyl ether (PGEE)

ethyl-3-ethoxypropionate (FEP)

dipropylene glycol monethyl ether

tripropylene glycol monethyl ether

polypropylene glycol monethyl ether

propylene glycol monomethyl ether propionate

3-methoxy methyl propionate

3-ethoxy ethylpropionate

N-methyl-2-pyrrolidone

2. When the Photo Resist is Soluble in Water

(a) water

(b) aqueous solution having water as main ingredient

By using the substrate processing system 100 according to the present embodiment and the exposure process gas 33, the inventors of the present application actually performed reflow of a coating film which is patterned on a substrate as follows.

First, a coating film made of photo resist which has novolac type resin as main ingredient is applied on a substrate to a thickness of 2.0 μm, and coating film patterns are formed each of which has a width of 10.0 μm and a length of 20.0 μm. The coating film patterns were reflowed by using NMP as the exposure process gas 33 in the substrate processing system 100 according to the present embodiment. The conditions concerning N₂ gas and the like contained in the exposure process gas 33 were the same as those described in the first embodiment mentioned above.

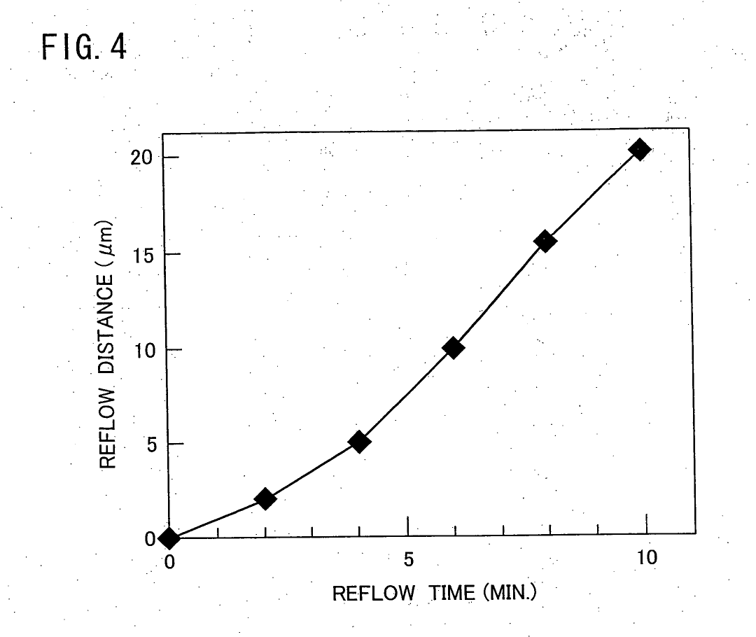

FIG. 4 is a graph showing a relationship between a reflow distance in lateral direction of a coating film pattern and a reflow time. In this case, main conditions of the reflow process other than those mentioned above are as follows.

(1) Exposure process gas and flow rate: vapor of the processing liquid 5 L/min; N₂ gas 5 L/min

(2) Temperature of the exposure process gas: 22° C.

(3) Distance between the lifting stage 11 and the gas spouting plate 21: 10 mm

(4) Temperature of the lifting stage 11: 26° C.

(5) Processing pressure within the exposure process chamber 101: +0.2 KPa

As can be seen from FIG. 4, the reflow distance of the coating film pattern varies approximately linearly with a variation of the reflow time. Therefore, it is possible to control the reflow distance by controlling the reflow time.

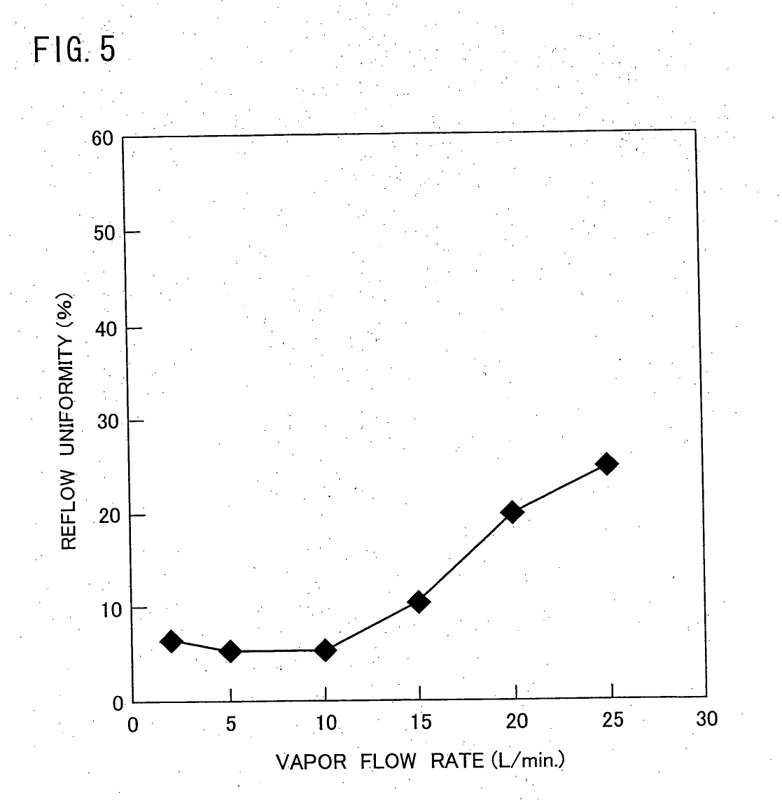

FIG. 5 is a graph showing uniformity of reflow distances within a substrate, after performing a reflow of the coating film patterns.

Among the reflow conditions shown in FIG. 4, the reflow time, the temperature of the processing gas, the distance between the lifting stage 11 and the gas spouting plate 21, the temperature of the lifting stage 11 and the processing pressure within the exposure process chamber 101 were fixed, and the flow rate of the processing gas was varied. Conditions other than those were the same as the conditions used in the description concerning FIG. 4.

When obtaining the relationships shown in FIG. 5, the reflow time of the coating film patterns was 5 minutes, and reflow distances of the coating film patterns after the reflow were measured. The reflow distances were measured at 10 (ten) points on the substrate 1 which were selected uniformly throughout the surface of the substrate 1. Assume that, among the reflow distance values measured at the 10 points, the maximum value is Tmax, the minimum value is Tmin, and an average value is Tmean. In such case, dispersion Txs of a reflow distance Tx at a measurement point is shown by the following formula.
Txs=|(Tmean-−Tx)/Tmean|

As can be seen from FIG. 5, when the flow rate of the exposure process gas 33 is between 2 L/min and 10 L/min, the dispersion of the reflow distances within the substrate 1 is approximately 5% and very good result was obtained.

According to the experiments by the inventors of the present invention, it was found that, among the control factors of a reflow process, quantity of supply of the exposure process gas 33 to the photo resist patterns is most important. It is also possible to freely control the reflow distance, by providing the gas spouting plate 21, and by controlling the supply of the exposure process gas 33 depending on a location of the substrate 1.

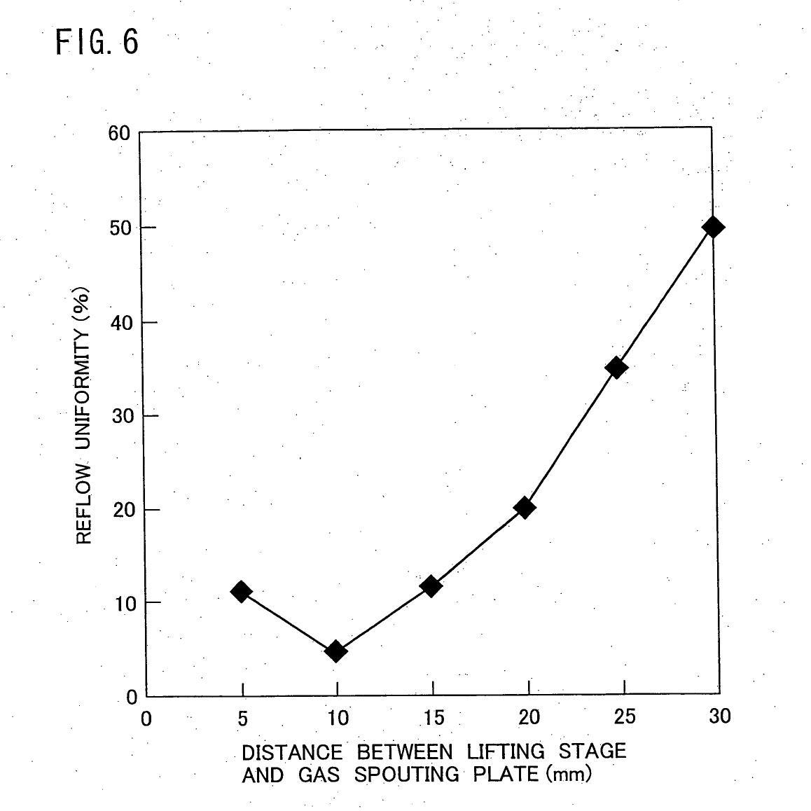

FIG. 6 is a graph showing a relationship between a uniformity of reflow distances within a substrate after reflowing a coating film pattern and a distance between the lifting stage 11 and the gas spouting plate 21.

When obtaining the relationship of FIG. 6, among the reflow conditions shown above concerning FIG. 4, the reflow time, the temperature of the processing gas, the flow rate of the exposure process gas, the temperature of the lifting stage 11 and the processing pressure within the exposure process chamber 101 were fixed, and the distance between the lifting stage 11 and the gas spouting plate 21 was varied.

As apparent from FIG. 6, when the distance between the lifting stage 11 and the gas spouting plate 21 is adjusted to a value within a range between 5 and 15 mm, it is possible to decrease variation of the reflow distances within the area of the substrate 1 to approximately 10% or smaller.

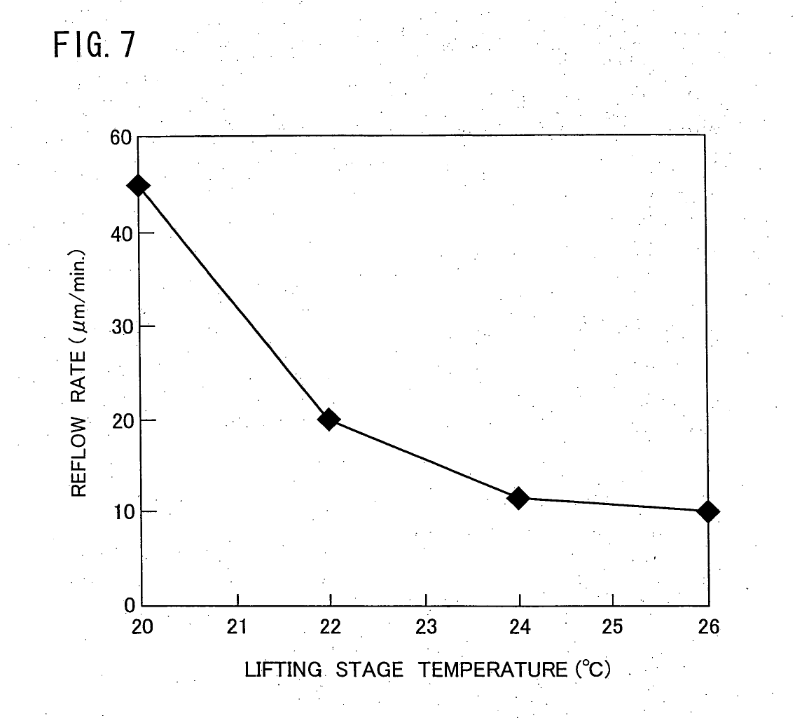

FIG. 7 is a graph showing a relationship between a reflow rate or reflow speed of a coating film pattern and a temperature of the lifting stage.

In this case, among the reflow conditions shown in FIG. 4, the reflow time, the temperature of the processing gas, the flow rate of the processing gas, the distance between the lifting stage 11 and the gas spouting plate 21 and the processing pressure within the exposure process chamber 101 were fixed, and the temperature of the lifting stage 11 was varied.

As can be seen from FIG. 7, by controlling the temperature of the lifting stage 11 to become 24-26° C., the reflow rate of a coating film pattern becomes approximately 10 μm/min and is stabilized.

From the above-mentioned result of measurements, under the conditions indicated below, it is possible, in the substrate processing system 100 according to the present invention, to decrease dispersion of the reflow distances within the area of the substrate 1 to approximately 10% or smaller, while retaining the function as a mask.

(1) Exposure process gas and flow rate: vapor of the processing liquid 2-10 L/min; N₂ gas 2-10 L/min

(2) Temperature of the exposure process gas: 20-26° C.

(3) Distance between the lifting stage 11 and the gas spouting plate 21: 5-15 mm

(4) Temperature of the lifting stage 11: 24-26° C.

(5) Processing pressure within the exposure process chamber 101: from −1 to +2 KPa

In the above, the substrate processing system 100 according to the present embodiment was explained as a system for performing reflow of a photo resist film. However, the substrate processing system 100 may be used for an object other than reflow of a photo resist film. For example, it is possible to use the substrate processing system 100 for cleaning the surface of a semiconductor substrate by using acid, for improving adhesion of a photo resist to a substrate, and the like. In such case, the following chemicals are used.

(A) Solutions Having Acid as Main Ingredient (For Use in Surface Cleaning)

hydrochloric acid

hydrogen fluoride

other acid solution

(B) Inorganic-Organic Mixed Solution (For Use in Strengthening Adhesion of an Organic Film)

silane coupling agent such as hexamethyldisilazane and the like

### Second Embodiment

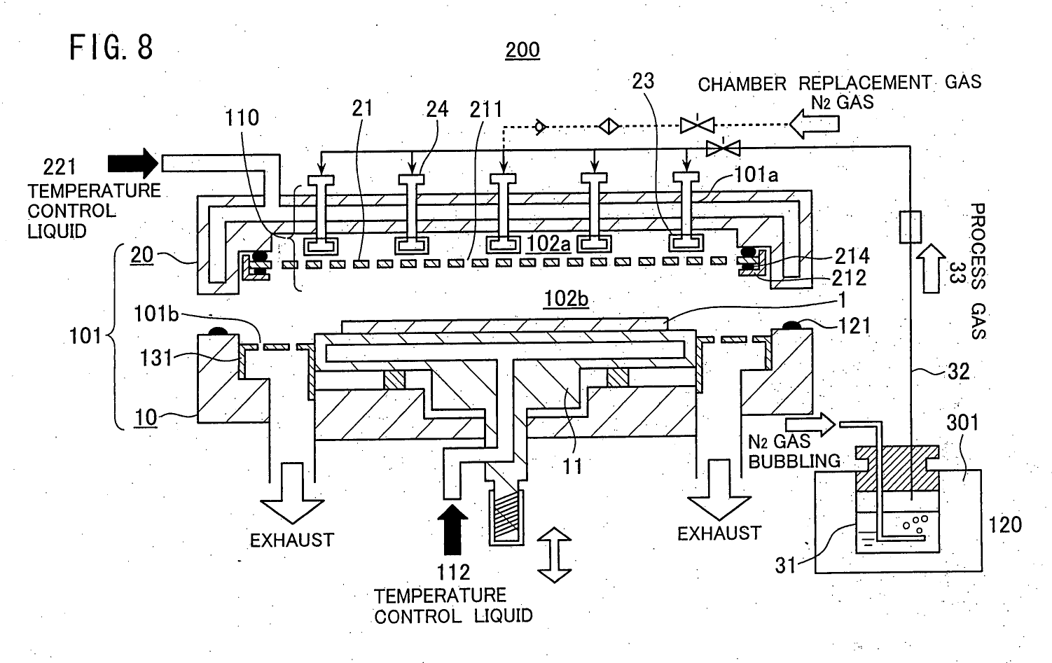

FIG. 8 is a cross sectional view illustrating a schematic structure of a substrate processing system according to the second embodiment of the present invention. Similarly to the substrate processing system 100 according to the first embodiment, the substrate processing system 200 according to the second embodiment can also be used for spraying exposure process gas uniformly onto a substrate disposed within a chamber.

In FIG. 8, portions having the same structures and functions as those of the components of the substrate processing system 100 according to the first embodiment are designated by the same reference numerals

According to experiments by the inventors of the present invention, it was found that, in order to stabilize and uniform the treatment process onto the substrate 1 and also to control the reaction speed or rate, it is necessary to control the temperature of each portion of the substrate processing system. Therefore, in the substrate processing system 200 according to the present embodiment, temperature control mechanisms are provided as follows.

In the lower chamber 10, in order to control the temperature of the substrate 1, an inner portion of the lifting stage 11 is made hollow. Temperature control liquid 112 is supplied to the inner portion of the lifting stage 11 such that the temperature control liquid 112 circulates in the lifting stage 11. Thereby, temperature of the whole portion of the lifting stage 11 is appropriately controlled.

Also, an inner portion of the upper chamber 20 is made hollow, and temperature control liquid 221 is supplied to the inner portion of the upper chamber 20 such that the temperature control liquid 221 circulates in the upper chamber 20. Thereby, not only the temperature of the upper chamber 20 is controlled by the temperature control liquid 221, but also the temperature of the gas introducing pipes 24, the gas diffusing members 23 and gas spouting plate 21 which connect with the upper chamber 20 is controlled by heat conduction.

In the gas introducing mechanism 120, in order to control the temperature of the supplied exposure process gas 33, an inner portion of the storing reservoir 301 is made hollow. Temperature control liquid is supplied to the inner portion of the storing reservoir 301 such that the temperature control liquid circulates in the storing reservoir 301. Thereby, temperature of the exposure process gas 33 is appropriately controlled.

As a temperature range through which the temperature of the above-mentioned various portions can be controlled, it is required that the temperature can be controlled in a range from 10 to 80° C., more particularly in a range from 20 to 50° C. Also, it was found that it is required that the temperature can be controlled with a precision of ±3° C., more preferably ±0.5° C.

Now, an explanation will be made on an operation the substrate processing system 200 according to the second embodiment of the present invention, and on a processing method of the substrate 1 which uses the substrate processing system 200.

First, the temperature of the temperature control liquid 112 is adjusted to 24° C., and both the temperature of the lifting stage 11 and the temperature of the substrate 1 are controlled to become the same temperature of 24° C.

Also, the temperature of the temperature control liquid supplied to the storing reservoir 301 is adjusted to 26° C., and the exposure process gas 33 from the gas spray mechanism 110 is controlled to become the same temperature.

The temperature of the temperature control liquid 221 is also adjusted to 26° C., and the temperature of the gas spouting plate 21, the upper chamber 20 and gas diffusing members 23 is controlled to become the same temperature.

Thereafter, process steps similar to those performed by using the substrate processing system 100 according to the first embodiment are performed.

### Variations of First and Second Embodiments

Structures of the above-mentioned substrate processing system 100 according to the first embodiment and the substrate processing system 200 according to the second embodiment are not limited to those mentioned above, but can be modified in various ways as mentioned below.

First, the gas spray mechanism 110 can be modified as follows.

In the substrate processing systems 100 and 200 according to the first and second embodiments, it is proposed that one gas flow rate control mechanism is provided on the upper side of the gas introducing pipes 24, and the exposure process gas 33 is distributed from the gas flow rate control mechanism to each of the gas introducing pipes 24. However, it is also possible to provide a gas flow rate control mechanism at each of the gas introducing pipes 24 for adjusting the flow rate thereof. The gas flow rate control mechanism may be any type of mechanism for controlling a flow rate of the exposure process gas 33. For example, it is possible to control the gas flow rate by performing mass flow control, control by using a flow meter, control of an opening angle of a valve, and the like to control a flow of the exposure process gas 33.

In the substrate processing system 100 according to the first embodiment of the present invention, a plurality of gas diffusing members 23 are all disposed within the first space 102a. However, it is also possible to divide the first space 102a into a plurality of small spaces by surrounding one gas introducing pipe 24 or a plurality of gas introducing pipes 24 with partitions, and to dispose one or more gas diffusing members 23 in each of the small spaces.

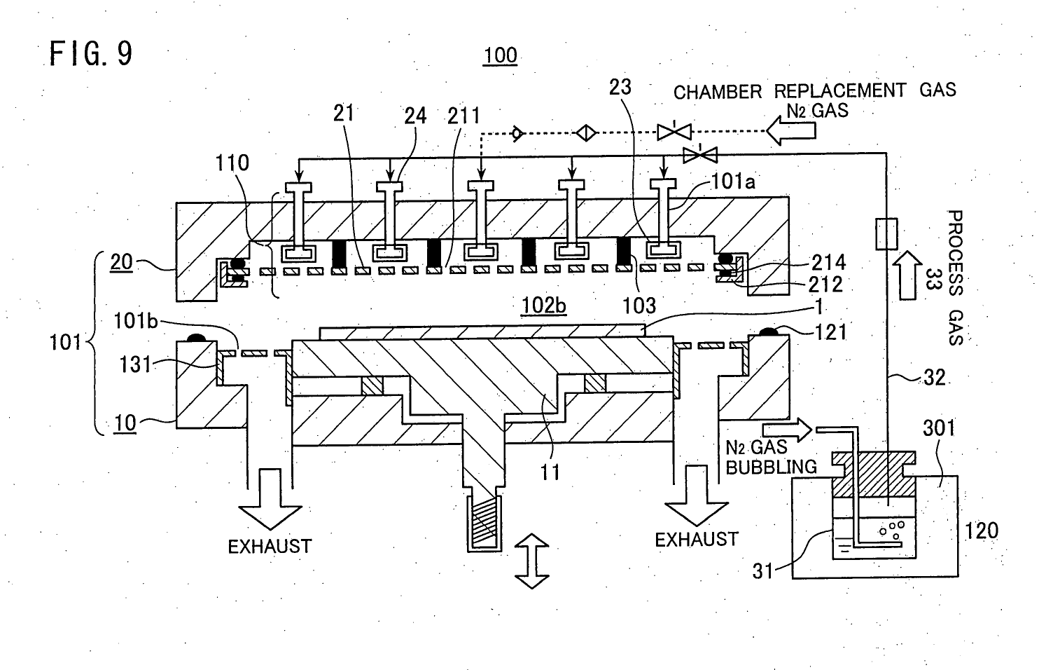

FIG. 9 is a cross sectional view illustrating an example of such substrate processing system in which partitions are provided in the first space 102a such that each one of the gas introducing pipes 24 is surrounded by the partitions 103.

In this structure, when the exposure process gas 33 is spouted out from each of the small space into the second space 102b via the gas spouting plate 21, it is possible to control gas flow every gas introducing pipe 24, i.e., every small space. Therefore, it is possible to control gas flow for each location within the second space 102b. As a result thereof, it is possible to spout or spray the exposure process gas 33 with uniform density onto the substrate 1 placed within the second space 102b, regardless of the location on the substrate 1. If desired, it is also possible to spray the exposure process gas 33 onto the substrate 1 placed within the second space 102b with a desired distribution of gas density.

In this case, it is not always necessary to completely seal between the above-mentioned small spaces by the partitions 103. It is also possible to provide one or more holes or gaps in each of the partitions 103 such that adjacent small spaces partially communicate with each other and gas can come and go therebetween.

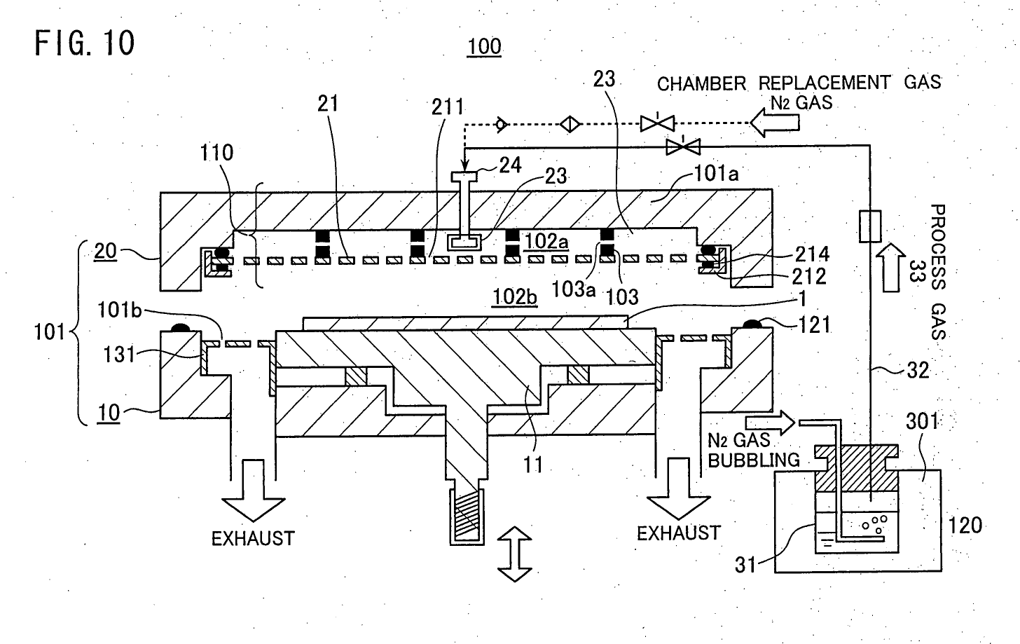

When the first space 102a is divided into a plurality of small spaces by using the partitions 103, it is not always necessary that each of the small spaces includes one gas introducing pipe 24. For example, as shown in FIG. 10, only one gas introducing pipe 24 may be disposed in any one of the plurality of small spaces. In such case, each of the partitions has hole or holes 103a, and the exposure process gas 33 spouted from the gas introducing pipe 24 is distributed into whole small spaces via the holes 103a.

In the substrate processing system 100 according to the first embodiment of the present invention, the gas spouting plate 21 is formed as a flat plate member. However, it is also possible to form the gas spouting plate 21 from a curved plate member which has a convex or concave surface toward the substrate 1.

Also, in the substrate processing system 100 according to the first embodiment of the present invention, the gas spouting plate 21 is fixed to the upper chamber 20. However, it is also possible to make the gas spouting plate 21 rotatable around the center of the gas spouting plate 21 as the rotating center. For example, while the exposure process gas 33 is sprayed onto the substrate 1, it is possible to rotate the gas spouting plate 21 by using a driving source, for example, an electric motor and the like and thereby to spray the exposure process gas 33 onto the substrate 1 more uniformly.

Further, not only the gas spouting plate 21, but also the lifting stage 11 may be made rotatable around the center shaft thereof as the rotating center.

For example, it is possible to rotate both the gas spouting plate 21 and the lifting stage 11 mutually in opposite direction, and thereby to spray the exposure process gas 33 more uniformly onto the substrate 1.

It is also possible to provide a pressure sensing element within the exposure process chamber 101 for measuring an inner pressure of the exposure process chamber 101, and to operate a vacuum exhaust system for exhausting from the exposure process chamber 101, in accordance with the pressure measured by the pressure sensing element. Thereby, the inner pressure of the exposure process chamber 101 can be automatically controlled.

### Third Embodiment

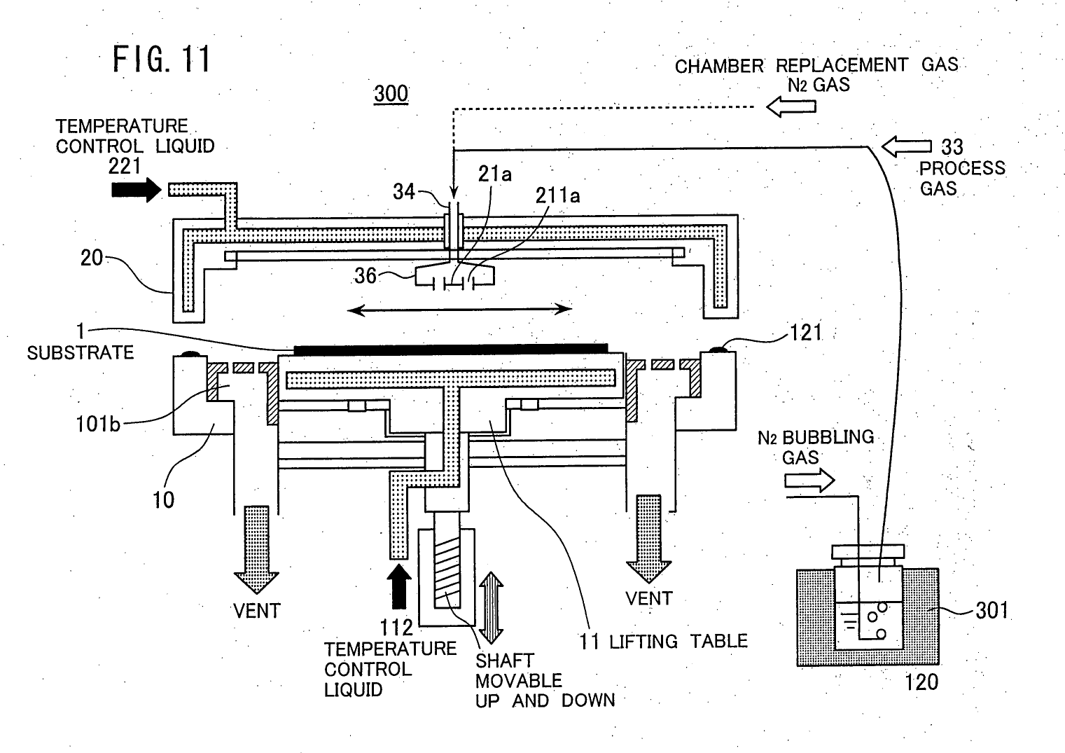

FIG. 11 is a cross sectional view illustrating a schematic structure of a substrate processing system according to the third embodiment of the present invention. Similarly to the substrate processing system 100 according to the first embodiment, the substrate processing system 300 according to the third embodiment can also be used for spraying exposure process gas uniformly onto a substrate disposed within a chamber.

In FIG. 11, portions having the same structures and functions as those of the components of the substrate processing system 100 according to the first embodiment are designated by the same reference numerals.

The substrate processing system 300 according to the present embodiment comprises a movable gas introducing pipe 34 and a gas spray member 36 attached to the lower end portion of the movable gas introducing pipe 34, in place of a plurality of gas introducing pipes 24, a plurality of gas diffusing members 23 and the gas spouting plate 21 in the substrate processing system 100 according to the first embodiment.

In the upper chamber 20 in the substrate processing system 300 according to the present embodiment, a slit not shown in the drawing is provided which extends along the length direction of the substrate 1, i.e., a lateral direction of FIG. 11. The movable gas introducing pipe 34 can slide within this slit.

The movable gas introducing pipe 34 is driven by an electric motor not shown in the drawing and slides along the slit. In this case, even when the movable gas introducing pipe 34 slides along the slit, inside space of the exposure process chamber 101 is maintained airtight.

The upper end of the movable gas introducing pipe 34 is connected with the gas pipe 32, and the exposure process gas 33 is supplied to the chamber via the gas pipe 32.

To the lower end of the movable gas introducing pipe 34, there is attached a gas spraying portion 36. The gas spraying portion 36 has a hollow structure, and has a lower end opening portion to which a gas spouting plate 21a having a plurality of openings 211a is attached.

The gas spraying portion 36 has the same function as that of the gas diffusing members 23. Therefore, the exposure process gas 33 introduced into the gas spraying portion 36 via the gas pipe 32 and the movable gas introducing pipe 34 diffuses once within the gas spraying portion 36. After the density of the exposure process gas 33 becomes uniform within the gas spraying portion 36, the exposure process gas 33 is sprayed onto the substrate 1 via the openings 211a of the gas spouting plate 21a.

Although not shown in detail in the drawing, the gas spraying portion 36 is rotatably attached to the movable gas introducing pipe 34 such that the gas spraying portion 36 can rotate around the center axis thereof, by using, for example, an electric motor not shown in the drawing.

In the substrate processing system 300 according to the present embodiment, the movable gas introducing pipe 34 moves along the slit provided in the upper chamber 20 in the longitudinal direction of the substrate 1. While the movable gas introducing pipe 34 is moving in the longitudinal direction, the gas spraying portion 36 sprays the exposure process gas 33 supplied from the vapor producing device 31 onto the substrate 1.

In this way, the gas spraying portion 36 sprays the exposure process gas 33 onto the substrate 1 while the gas spraying portion 36 scans along the substrate 1. Therefore, it is possible to spray the exposure process gas 33 uniformly onto the substrate 1.

Additionally, while the movable gas introducing pipe 34 moves along the slit of the upper chamber 20 in the longitudinal direction of the substrate 1, the gas spraying portion 36 rotates around the center axis thereof. Therefore, it is possible to spray the exposure process gas 33 more uniformly onto the substrate 1.

In the above-mentioned substrate processing system 300 according to the third embodiment, it is also possible to make the gas spraying portion 36 movable up and down. For example, the movable gas introducing pipe 34 may have a double tube structure which includes an inner tube and an outer tube and in which, for example, the inner tube can freely slide with respect to the outer tube. Also, the gas spraying portion 36 is attached to the inner tube, and thereby the gas spraying portion 36 can be made freely sidable up and down with respect to the outer tube. Therefore, the distance between the substrate 1 and the gas spraying portion 36 can be freely controlled.

In this way, when the gas spraying portion 36 is movable up and down, it is not always necessary for the lifting stage 11 to be able to move up and down. However, it is also possible to make both the gas spraying portion 36 and the lifting stage 11 movable up and down.

### Fourth Embodiment

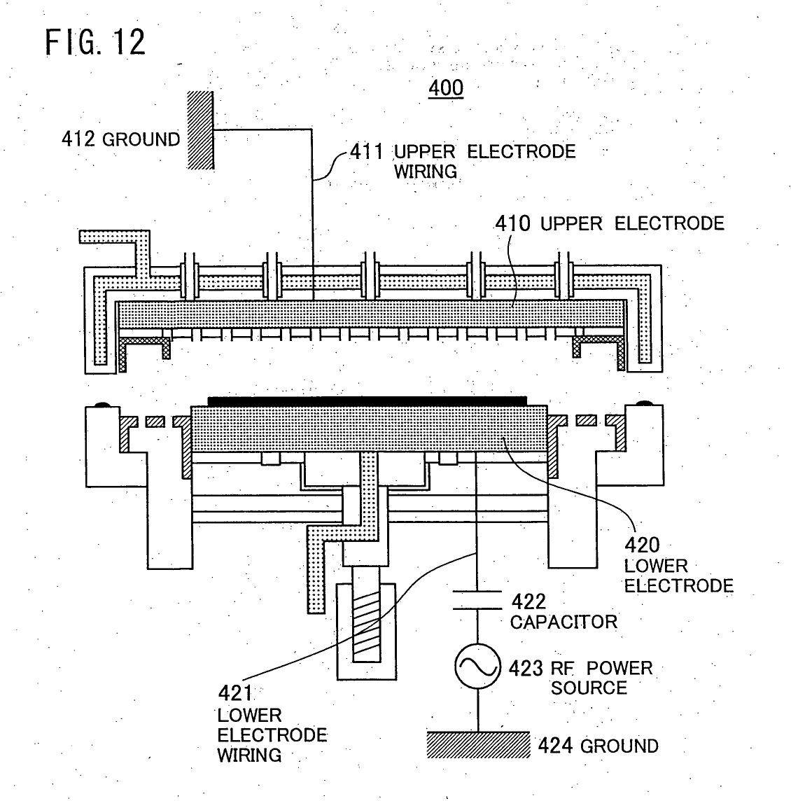

FIG. 12 is a cross sectional view illustrating a schematic structure of a substrate processing system according to the fourth embodiment of the present invention. As mentioned above, the substrate processing system 100 according to the first embodiment can be used for spraying exposure process gas uniformly onto a substrate disposed within a chamber, while the substrate processing system 400 according to the fourth embodiment can be used for spraying exposure process gas uniformly onto a substrate disposed within a chamber and also for performing dry etching process or ashing process onto the substrate.

In this case, it is possible to perform the dry etching or the ashing process either before or after the exposure process. Also, it is possible to perform the dry etching or the ashing process simultaneously with the exposure process.

In FIG. 12, portions having the same structures and functions as those of the components of the substrate processing system 100 according to the first embodiment are designated by the same reference numerals.

The substrate processing system 400 according to the present embodiment comprises, in addition to the components of the substrate processing system 100 of the first embodiment, a plasma generating means. The plasma generating means comprises an upper electrode 410 disposed between the upper chamber 20 and the gas spouting plate 21, a lower electrode 420 disposed inside the lifting stage 11, a capacitor 422 and an RF high frequency power source 423.

The upper electrode 410 is coupled with the ground via a upper electrode wiring conductor 411.

Also, the lower electrode 420 is coupled to one terminal of the RF high frequency power source 423 via a lower electrode wiring conductor 421 and the capacitor 422. The other terminal of the RF high frequency power source 423 is coupled to the ground.

In the substrate processing system 400 according to the present embodiment, the exposure process and dry etching or ashing process are performed onto the substrate 1 in a manner mentioned below.

First, on the substrate 1, patterns of a film to be etched are formed. Further, mask patterns of a photo resist film (hereafter, called “a photo resist mask”) which are formed on the patterns of a film to be etched are deformed in a manner similar to the first embodiment. That is, the substrate 1 is exposed to the exposure process gas 33, and thereby the photo resist mask is dissolved and reflowed to deform the patterns thereof.

Here, at the time when the photo resist mask deforms by dissolution and reflow or thereabout, etching can be performed on the patterns of the film to be etched which are formed on the substrate 1 by using a photo resist mask having different patterns.

Thereby, it is possible to form two kinds of etching patterns as patterns of the film to be etched.

In this case, a process called an ashing process which uses O₂ plasma is also performed on the photo resist mask.

The dry etching or ashing process in the substrate processing system 400 according to the present embodiment is performed as follows. In this case, the dry etching or ashing process performed in the substrate processing system 400 according to the present embodiment is similar to the conventional dry etching or ashing process.

First, the substrate 1 is mounted within the exposure process chamber 101, and the exposure process chamber 101 is vacuum evacuated to remove residual gas within the chamber. In this case, the pressure within the exposure process chamber 101 is approximately 1 Pa or lower.

Then, in case the dry etching process is performed, etching gas, for example, Cl₂/O₂/He mixed gas is introduced into the exposure process chamber 101 (when a metal such as Cr and the like is etched). In case the ashing process is performed, gas, for example, O₂ gas, O₂/CF₄ mixed gas or the like is introduced into the exposure process chamber 101.

The pressure within the exposure process chamber 101 is kept constant at a pressure in a range from 10 Pa to 120 Pa.

Next, a plasma discharge is performed between the upper electrode 410 and the lower electrode 420 by using the RF high frequency power source 623 and the capacitor 622, thereby dry etching or ashing is performed onto the substrate 1.

In this embodiment, the lower electrode 420 is coupled with the ground via the capacitor 622 and the RF high frequency power source 623. However, it is also possible to ground the lower electrode 420 only via the RF high frequency power source 623.

Also, in this embodiment, the upper electrode 410 is directly coupled with the ground and the lower electrode 420 is coupled with the ground via the capacitor 622 and the RF high frequency power source 623. However, on the contrary, it is possible to couple the lower electrode 420 directly with the ground, and to couple the upper electrode 410 with the ground via the capacitor 622 and the RF high frequency power source 623 or only via the RF high frequency power source 623.

Further, the plasma generating mechanism for producing plasma within the exposure process chamber 101 is not limited to the plasma generating mechanism according to the present embodiment, but can be any other plasma generating mechanism.

As mentioned above, according to the substrate processing system 400 of the above-mentioned embodiment, it is possible to perform both the exposure process and dry etching or ashing process onto the substrate 1 by using one chamber.

The exposure process gas 33 used in the exposure process and various gases used in the dry etching or ashing process can be introduced into the exposure process chamber 101 via separate gas introducing mechanisms, or can be introduced into the exposure process chamber 101 by commonly using a single gas introducing mechanism. In this case, when the exposure process and the dry etching or ashing process are to be performed simultaneously or approximately simultaneously, it is necessary to provide separate gas introducing mechanisms.

Also, similarly to the substrate processing system 200 according to the second embodiment, in the substrate processing system 400 according to the present embodiment, it is possible to provide temperature control mechanism for maintaining the temperature of the upper electrode 410 and the lower electrode 420 at constant value or values.

### Fifth Embodiment

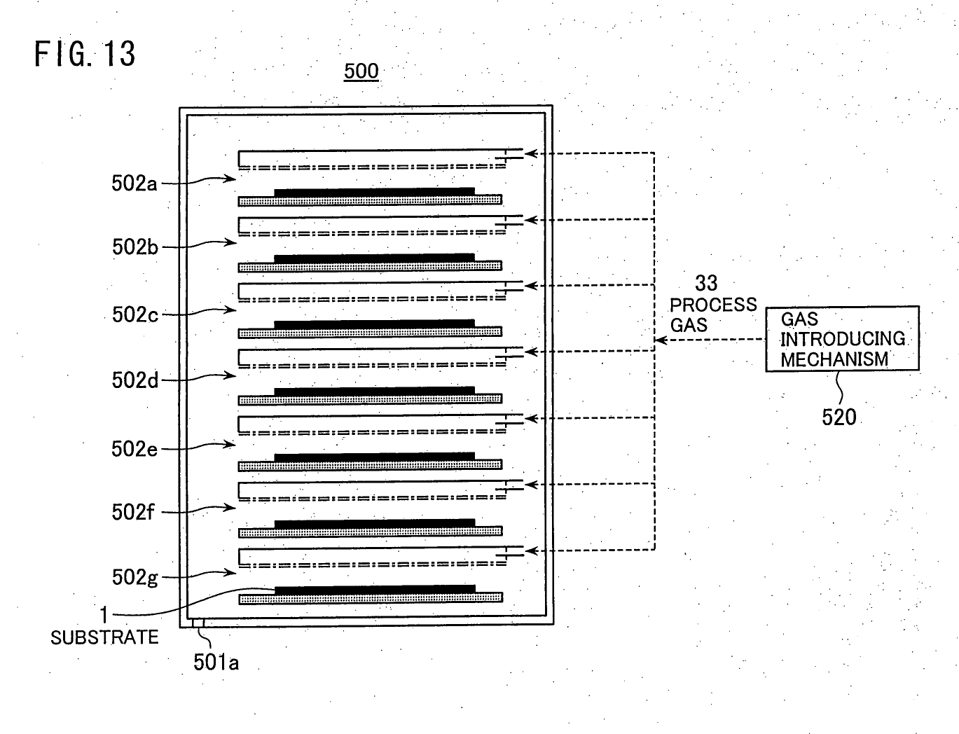

FIG. 13 is a cross sectional view illustrating a schematic structure of a substrate processing system according to the fifth embodiment of the present invention. The substrate processing system 500 according to the fifth embodiment can be used as a system for uniformly spraying exposure process gas 33 onto substrates disposed within a chamber, or can be used as a system for performing both exposure process and dry etching or ashing process.

In FIG. 13, portions having the same structures and functions as those of the components of the substrate processing system 100 according to the first embodiment are designated by the same reference numerals.

As shown in FIG. 13, the substrate processing system 500 comprises: a chamber 501 having a gas outlet 501a; seven stage substrate processing units 502a, 502b, 502c, 502d, 502e, 502f and 502g; and a gas introducing mechanism 520. The gas introducing mechanism 520 may be the same as the gas introducing mechanism 120 in the first embodiment.

The seven stage substrate processing units 502a-502g are disposed in a vertical direction within the chamber 501. Each of the seven stage substrate processing units 502a-502g has approximately the same structure as the structure obtained by removing the exposure process chamber 101 and the gas introducing mechanism 120 from the substrate processing system 100 in the first embodiment shown in FIG. 1.

The gas introducing mechanism 520 has the same structure as that of the gas introducing mechanism 120 in the first embodiment, and commonly supplies the exposure process gas 33 to each of the seven stage substrate processing units 502a-502g.

The substrate processing system 100 according to the first embodiment of the present invention is a batch type substrate processing system in which the substrate 1 is processed one by one. On the other hand, the substrate processing system 500 of the present embodiment can process a plurality of substrates 1 at the same time. Therefore, when compared with the substrate processing system 100 according to the first embodiment, the substrate processing system 500 according to the present embodiment can process the substrates with very high processing efficiency.

The substrate processing system 500 according to the present embodiment and mentioned above has seven stage substrate processing units 502a-502g. However, the number of the substrate processing units is not limited to seven, but can be any suitable number larger than one.

Also, in the substrate processing system 500 according to the present embodiment, each of the substrate processing units 502a-502g has the structure similar to that of the corresponding portion of the substrate processing system 100 according to the first embodiment. However, it is also possible to constitute each of the substrate processing units 502a-502g based on the substrate processing system 200, 300 or 400 according to the second, third or fourth embodiment of the present invention.

### Sixth Embodiment

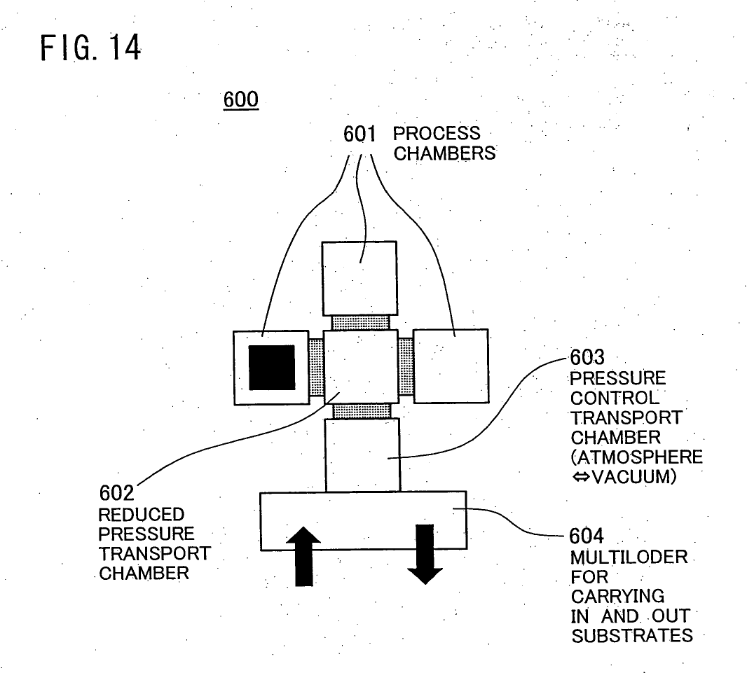

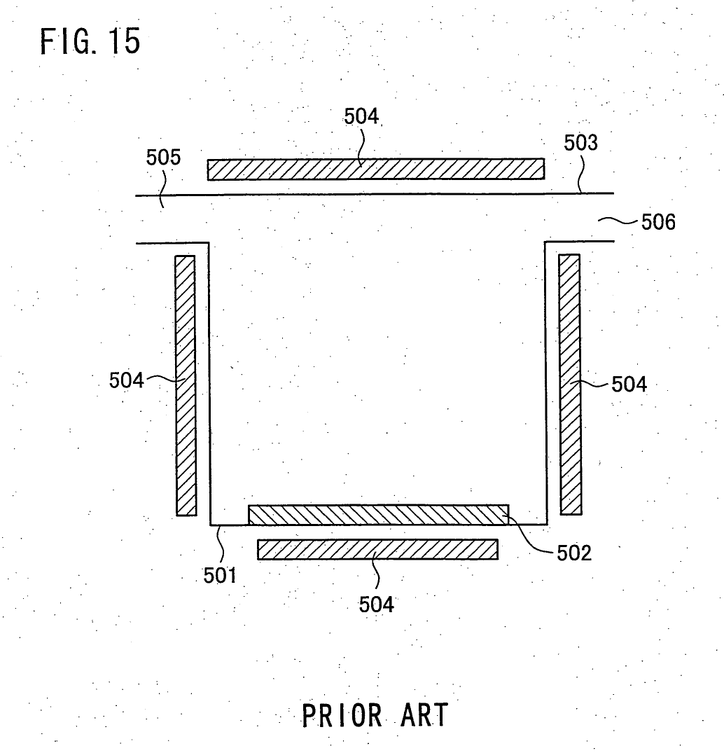

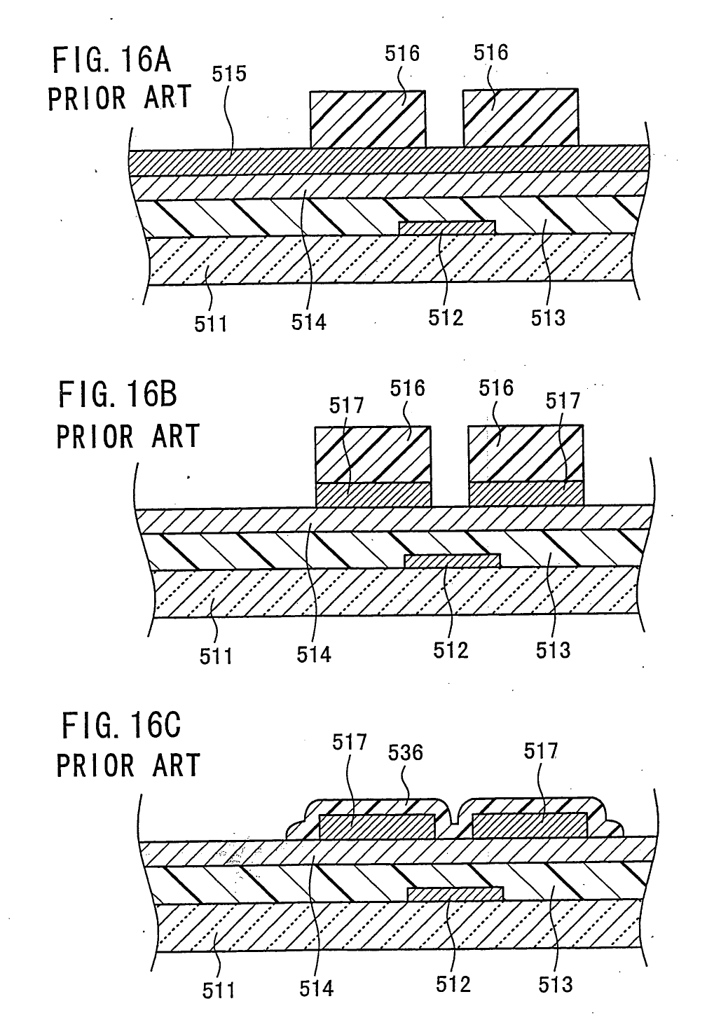

FIG. 14 is a plan view illustrating a schematic structure of a substrate processing system according to the sixth embodiment of the present invention. The substrate processing system 600 according to the present embodiment can continuously perform a series of processes from a process of transporting substrate or substrates to be processed from the atmosphere to exposure process chambers, to a process of again returning the substrate or substrates from the exposure process chambers to the atmosphere after processing the substrate or substrates.

The substrate processing system 600 according to the present embodiment comprises three process chambers 601, a reduced pressure transport chamber 602, a pressure controlled transport chamber 603, and a transport mechanism 604 for carrying substrates into or out of the substrate processing system 600.

The reduced pressure transport chamber 602 communicates with each of the three process chambers 601. The reduced pressure transport chamber 602 carries substrates to be processed into process chambers 601 under a reduced pressure condition, and carries out processed substrates from the process chambers 601 under a reduced pressure condition.

The pressure controlling transport chamber 603 communicates with the reduced pressure transport chamber 602. The pressure controlling transport chamber 603 accepts substrates before processing from outside under the atmospheric pressure, and carries the substrates into the reduced pressure transport chamber 602 under a reduced pressure condition. The pressure controlled transport chamber 603 also carries out the processed substrates from the reduced pressure transport chamber 602 under a reduced pressure condition, and carries out the substrates outside under the atmospheric pressure.

The transport mechanism 604 transports the substrates from outside into the pressure controlling transport chamber 603, and transports the substrates from the pressure controlling transport chamber 603 to outside. The transport mechanism 604 may, for example, a multi-loader mechanism and the like.

Each of the three process chambers 601 may have a structure similar to that of any of the substrate processing systems 100, 200, 300, 400 and 500 according to the first through fifth embodiments of the present invention.

An explanation will now be made on an operation of the substrate processing system 600 according to the present embodiment.

First, a substrate to be processed is carried into the pressure controlled transport chamber 603 via the transport mechanism 604 under the atmospheric pressure.

After the substrate is carried into the pressure controlled transport chamber 603, the pressure controlled transport chamber 603 is closed from the transport mechanism 604. The pressure within the pressure controlled transport chamber 603 is then reduced and becomes vacuum condition. Under this condition, the substrate is transported from the pressure controlled transport chamber 603 to the reduced pressure transport chamber 602. The reduced pressure transport chamber 602 is always kept in vacuum condition.

Next, the substrate is transported from the reduced pressure transport chamber 602 to any one of the process chambers 601, and in that process chamber 601 the substrate is processed. For example, exposure process or ashing process is performed onto the substrate.

After the process is finished, the substrate is transported from the process chamber 601 to the reduced pressure transport chamber 602. If necessary, the substrate is again transported to another process chamber 601 and another kind of process is performed.

The substrate is then transported from the reduced pressure transport chamber 602 to the pressure controlled transport chamber 603 which is in vacuum condition. After the substrate is transported into the pressure controlled transport chamber 603, the pressure within the pressure controlled transport chamber 603 is raised and is changed from vacuum condition to the atmospheric pressure.

The closure of the pressure controlled transport chamber 603 from the transport mechanism 604 is released, and the substrate after the process is carried out into the transport mechanism 604.

The transport mechanism 604 is then transports the substrate outside of the substrate processing system 600.

In this way, by using the substrate processing system 600, it is possible to process substrates continuously.

As mentioned above, by using the substrate processing system according to the present invention, it is possible to apply the exposure process gas approximately uniformly throughout the whole surface of each substrate. Therefore, it is possible to control the reflow distance L with high precision throughout the whole surface of the substrate.

Further, according to the present invention, it is possible to perform dry etching or ashing process onto the substrate, before and after the exposure process or simultaneously with the exposure process.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative sense rather than a restrictive sense, and all such modifications are to be included within the scope of the present invention. Therefore, it is intended that this invention encompasses all of the variations and modifications as falling within the scope of the appended claims.

1.-18. (canceled)

19. A substrate processing system which sprays exposure process gas onto each of a plurality of substrates horizontally disposed and vertically spaced away from one another in a chamber,
the chamber having at least one gas inlet and at least one gas outlet, said system comprising:
a gas introducing means which introduces the exposure process gas into the chamber via the gas inlet; and
a plurality of gas distributing means each associated with each of the plurality of substrates,
each of the gas introducing means having a plurality of openings, wherein the exposure process gas having been introduced via the gas introducing means is sprayed onto an associated substrate via the opening.

20. The substrate processing system as set forth in claim 19, wherein each of the plurality of gas distributing means is disposed facing an associated substrate.

21. The substrate processing system as set forth in claim 19, wherein the chamber has a plurality of the gas inlets.

22. The substrate processing system as set forth in claim 21, wherein each of the gas inlets is associated with each of the plurality of gas distributing means.

23. The substrate processing system as set forth in claim 22, further comprising a gas flow rate controller for each of the gas inlets.

24. The substrate processing system as set forth in claim 19, wherein each of the plurality of gas distributing means is in the form of a plate.

25. The substrate processing system as set forth in claim 24, wherein each of the plurality of gas distributing mean comprises a curved plate convex or concave toward an associated substrate.

26. The substrate processing system as set forth in claim 19, wherein each of the plurality of gas distributing means is rotatable around the center thereof.

27. The substrate processing system as set forth in claim 19, further comprising a plurality of gas spouting range defining means each of which is disposed so as to overlap each of the gas distributing means and closes a predetermined number of openings among the opening formed in each of the gas distributing means, thereby defining a gas spouting range of the exposure process gas.

28. The substrate processing system as set forth in claim 19, further comprising a stage on which the substrates are placed, the stage being movable up and down.

29. The substrate processing system as set forth in claim 19, further comprising a stage on which the substrates are placed, the stage being rotatable around the center axis thereof.

30. The substrate processing system as set forth in claim 19, further comprising a substrate temperature control means which controls the temperature of each of the substrates.

31. The substrate processing system as set forth in claim 19, further comprising a stage on which the substrates are placed, the substrate temperature control means controlling the temperature of each of the substrates by controlling the temperature of the stage.

32. The substrate processing system as set forth in claim 19, further comprising a gas temperature control means which controls the temperature of the exposure process gas.

33. The substrate processing system as set forth in claim 19, wherein a distance between each of the substrates and each of the gas distributing means in the chamber is in the range of 5 mm and 15 mm both inclusive.

34. The substrate processing system as set forth in claim 19, further comprising a plasma generating means which generates plasma within the chamber.

35. The substrate processing system as set forth in claim 34, wherein the plasma generating means comprises an upper electrode disposed above each of the substrates and a lower electrode disposed below each of the substrates,
wherein one of the upper and lower electrodes is grounded, and the other is grounded via a high frequency power source.

36. The substrate processing system as set forth in claim 19, further comprising:
a reduced pressure transport chamber which is communicated with the chamber and which is used for transporting each of the substrates into the chamber under a reduced pressure condition and for transporting each of the substrates out from the chamber under a reduced pressure condition; and
a pressure controlled transport chamber which is communicated with the reduced pressure transport chamber, which is used for introducing each of the substrates from outside under the atmospheric pressure condition and for transporting each of the substrates into the reduced pressure transport chamber under a reduced pressure condition and which is used for transporting each of the substrates out from the reduced pressure transport chamber under a reduced pressure condition and for transporting each of the substrates outside under the atmospheric pressure condition.
